(19) United States
(12) Patent Application Publication
(10) Pub. No.: US 2008/0292811 A1
(43) Pub. Date: Nov. 27, 2008

(54) CHAMBER IDLE PROCESS FOR IMPROVED REPEATABILITY OF FILMS

(76) Inventors: YOUNG-JIN CHOI, Santa Clara, CA (US); Soo Young Choi, Fremont, CA (US); Qunhua Wang, San Jose, CA (US); Weijie Wang, Cupertino, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/753,571

(22) Filed: May 25, 2007

(51) Int. Cl. C23C 16/00; H05H 1/24

(52) U.S. Cl. 427/569; 427/255.28; 427/255.29

(57) ABSTRACT

Methods and apparatus for improving the substrate-to-substrate uniformity of silicon-containing films deposited by vapor deposition of precursors vaporized from a liquid source on substrates in a chamber are provided. The methods include exposing a chamber to a processing step at a predetermined time that is after one substrate is processed in the chamber and is before the next substrate is processed in the chamber. In one aspect, the processing step includes introducing a flow of a silicon-containing precursor into the chamber for a period of time. In another aspect, the processing step includes exposing the chamber to a gas in the presence or absence of a plasma for a period of time.

### BACKGROUND OF THE INVENTION

1. Field of the Invention

Embodiments of the present invention generally relate to methods of improving the substrate-to-substrate uniformity of films deposited on a substrate in a chamber over time. In particular, embodiments of the invention relate to methods of improving the substrate-to-substrate uniformity of films deposited from precursors vaporized from liquid sources.

2. Description of the Related Art

Chemical vapor deposition (CVD) is a process that is commonly used to deposit films that are used as layers in devices on semiconductor substrates. Chemical vapor deposition generally includes generating vapors from a liquid or solid precursor and depositing a film from the vapors on a heated substrate surface in a chamber.

Examples of films that may be deposited by chemical vapor deposition include silicon-containing films. For example, chemical vapor deposition may be used to deposit the thin films of silicon and silicon oxide that are often used as layers in thin film transistors (TFTs) for large substrates, such as flat panel display substrates.

While CVD methods of depositing silicon-containing films with desirable properties such as good conformality have been developed, it can be difficult to repeat CVD processes in a chamber such that the processing conditions for each substrate processed sequentially in the chamber are identical, even when the chamber surfaces are maintained in a cleaned condition. Differences in the processing conditions for different substrates may affect substrate-to-substrate uniformity and quality. Such uniformity problems have been observed for tetraethoxysilane (TEOS) CVD processes.

Therefore, there remains a need for a method of improving the substrate-to-substrate uniformity of films deposited by vapor deposition.

### SUMMARY OF THE INVENTION

The present invention generally provides methods of processing substrates in a chamber. In one embodiment, the method comprises introducing a first flow of a precursor vaporized from a liquid source into a chamber and depositing a first film on a first substrate in the chamber. The precursor vaporized from a liquid source may be a silicon-containing precursor, such as TEOS. The flow of the precursor is then terminated and the substrate is removed from the chamber. A second flow of the precursor is introduced into the chamber at a predetermined time after the first flow of the precursor is terminated. No substrates are processed in the chamber between the removal of the first substrate and the introduction of the second flow of the precursor. The second flow of the precursor is continued for a period of time without a substrate being processed in the chamber during the period of time. If no substrates are processed in the chamber by a predetermined time after the second flow of the precursor is terminated, a third flow of the precursor may be introduced into the chamber.

In another embodiment, a first flow of a precursor vaporized from a liquid source is introduced into a chamber and a first film is deposited on a first substrate in the chamber. The precursor vaporized from a liquid source may be a silicon-containing precursor, such as TEOS. The flow of the precursor is then terminated and the substrate is removed from the chamber. At a predetermined time after terminating the first flow of the precursor into the chamber and after the first substrate is removed, one or more interior surfaces of the chamber are exposed to a gas in the presence or absence of a plasma for a first period of time without a substrate being processed in the chamber. The one or more interior surfaces of the chamber may be exposed to a gas to control the pressure in the chamber or fill the chamber in the presence or absence of a plasma in the chamber. Alternatively, the one or more interior surfaces may be exposed to a plasma with a gas that is provided to sustain the plasma in the chamber. No substrates are processed in the chamber between the removal of the first substrate and the exposure of the one or more interior surfaces of the chamber to the gas.

Further embodiments of the invention provide software routines comprising instructions for the methods provided herein.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow chart depicting an embodiment of the invention.

FIG. 2 is a schematic cross-sectional view of a plasma enhanced chemical vapor deposition system according to the prior art.

FIG. 3 is a flow chart depicting another embodiment of the invention.

### DETAILED DESCRIPTION

It has been observed that the processing conditions for the first substrate processed in a CVD chamber after the chamber has been sitting idle are often unstable, which can result in an unstable substrate-to-substrate deposition rate as well as other substrate-to-substrate variations. An example of a CVD process that has been observed to be susceptible to this “chamber idle effect” is a tetraethoxysilane (TEOS) CVD process. It has been observed that processes that use precursors, such as TEOS, that are vaporized from liquid sources are more susceptible to the chamber idle effect.

The present invention provides methods of improving the substrate-to-substrate uniformity of films deposited by vapor deposition of silicon-containing precursors vaporized from a liquid source, such as liquid silicon-containing precursors, on substrates in a chamber. Generally, the methods comprise exposing a chamber to a processing step during a chamber idle period that is between the deposition of a film on one substrate and the deposition of a film on the next substrate processed in the chamber and thus is a period in which no substrates are exposed to substrate processing, such as depositing a film on the substrate. The processing step during the chamber idle period may comprise introducing a gas into the chamber for a period of time, exposing one or more interior surfaces of the chamber to a plasma, or a combination thereof.

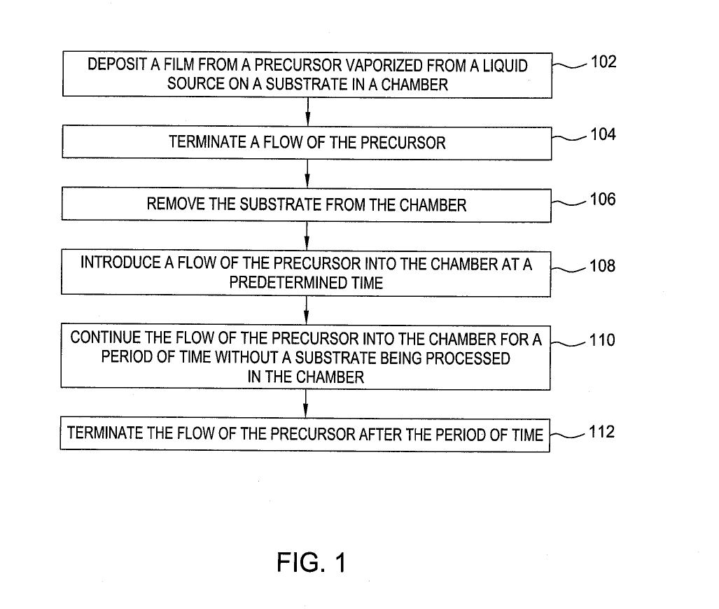

Embodiments of the invention that include introducing a gas into the chamber for a period of time during a chamber idle period will be described with respect to the flow chart in FIG. 1. A first flow of a precursor vaporized from a liquid source is introduced into a chamber, and a first film is deposited on a first substrate in the chamber, as summarized in step 102. The first film may be deposited by a vapor deposition process, such as chemical vapor deposition. In specific embodiments, the precursor is a silicon-containing precursor, such as tetraethoxysilane (TEOS), and the first film is a silicon-containing film, such as a silicon oxide layer, e.g., a SiO₂ layer. However, other precursors may be used, such as trimethylboron or other liquid organosilicon compounds. Other silicon-containing films that may be deposited include amorphous silicon films and silicon nitride films.

In one aspect, the film may be a TEOS-deposited silicon oxide layer that is used as a layer, such as a gate oxide layer, in a low temperature polysilicon (LTPS) TFT device for a flat panel display. However, it is recognized that the silicon-containing layer may be used to provide other types of layers for other devices.

In an embodiment in which the silicon-containing precursor is TEOS, the TEOS may be introduced into the chamber at a flow rate of between about 0.5 sccm/L of chamber volume and about 11.5 sccm/L of chamber volume (e.g., between about 100 sccm and about 2300 sccm for a chamber having a 200 L volume), such as between about 0.5 sccm/L and about 5 sccm/L (e.g., between about 100 sccm and about 1000 sccm for a chamber having a 200 L volume). An inert gas, such as helium or argon, may also be introduced into the chamber as a carrier gas. An oxidizing gas may be introduced into the chamber at a flow rate of between about 0.5 sccm/L and about 150 sccm/L (e.g., between about 100 sccm and about 30000 sccm for a chamber having a 200 L volume). The chamber pressure during the deposition may be between about 0.5 Torr and about 3 Torr, and the substrate temperature during the deposition may be between about 150° C. and about 450° C. RF power is provided to a gas distribution plate assembly electrode in the chamber at between about 0.015 W/cm² and about 1.12 W/cm² (e.g., between about 100 W and about 7500 W for an electrode having an area of 6716 cm²) at a frequency, such as 13.56 MHz, 27 MHz, 40 MHz, 60 MHz, or 80 MHz. The processing conditions described herein are provided with respect to an AKT-5500 PX chamber, which is a plasma enhanced CVD chamber available from Applied Materials, Inc. of Santa Clara, Calif. that may be used to process substrates up to 730 mm×920 mm. An AKT-5500 PX chamber may be used for any of the embodiments of the invention. Other chambers capable of performing CVD may also be used. For example, in order to process larger substrates, such as substrates having an area of about 40,000 cm² or greater, larger CVD chambers may be used.

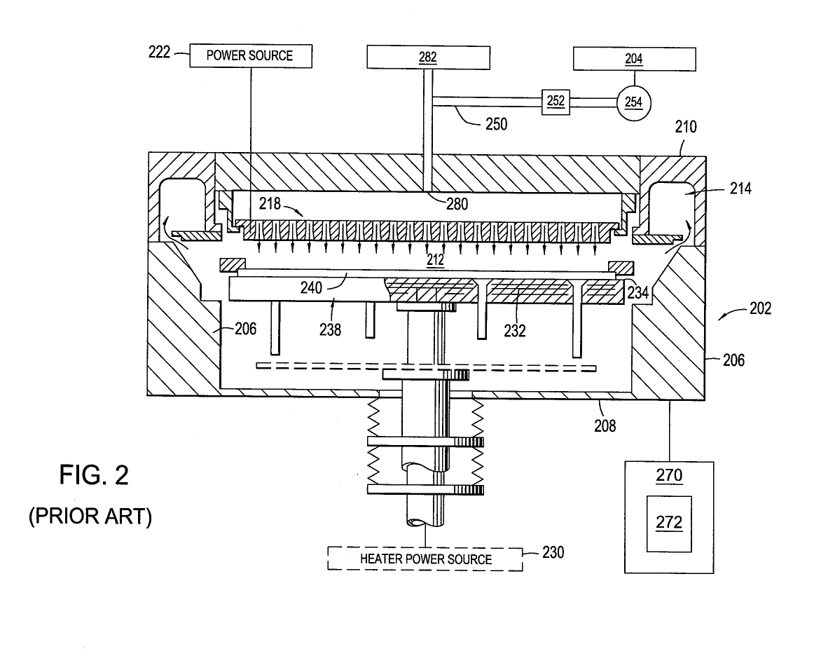

An example of a chamber that may be used is shown schematically in FIG. 2. The processing chamber 202 has walls 206 and a bottom 208 that partially define a process volume 212. The process volume 212 is typically accessed through a port (not shown) in the walls 206 that facilitate movement of a substrate 240 into and out of processing chamber 202. The walls 206 support a lid assembly 210 that contains a pumping plenum 214 that couples the process volume 212 to an exhaust port (that includes various pumping components, not shown).

A temperature controlled substrate support assembly 238 is centrally disposed within the processing chamber 202. The support assembly 238 supports the substrate 240 during processing. The substrate support assembly 238 typically encapsulates at least one embedded heater 232, such as a resistive element, which element is coupled to a power source 230 which is used to heat embedded heater elements 232 and controllably heats the support assembly 238 and the substrate 240 positioned on an upper surface 234 of the support assembly 238.

The support assembly 238 is generally grounded such that RF power supplied by a power source 222 to a gas distribution plate assembly 218 positioned between the lid assembly 210 and the substrate support assembly 238 (or other electrode positioned within or near the lid assembly of the chamber) may excite gases present in the process volume 212 between the support assembly 238 and the distribution plate assembly 218. The RF power from the power source 222 is generally selected to be commensurate with the size of the substrate to drive the chemical vapor deposition process.

The lid assembly 210 typically includes an entry port 280 through which process gases from a supply line 250 connected to the precursor source 204 are introduced into processing chamber 202. The entry port 280 is also coupled to a remote plasma source 282. The remote plasma source 282 may provide a cleaning agent, such as disassociated fluorine, that is introduced into the processing chamber 202 to remove deposition by-products and films from processing chamber hardware.

A vaporizer 252 may be located between the precursor source 204 and the chamber 202 for vaporizing a liquid precursor, such as a liquid silicon-containing precursor, before it is introduced into the chamber. It is believed that embodiments of the invention are particularly advantageous for deposition processes that use a liquid precursor, such as TEOS, as the clogging or bubbling around the liquid flow controller 254 may contribute to an unstable gas flow into the chamber that may result in substrate-to-substrate non-uniformity after a chamber idle period.

A controller 270 is also connected to the chamber. The controller 270 contains a computer storage medium 272 that contains a software routine comprising instructions for performing different processes in the chamber.

Returning to FIG. 1, after the film is deposited on the substrate, the flow of the precursor into the chamber is terminated, as shown in step 104. The substrate is then removed from the chamber, as shown in step 106. Then, if a period of time after the termination of the flow of the precursor elapses without another substrate being processed in the chamber, at a predetermined time, another flow of the precursor is introduced into the chamber, as shown in step 108. The predetermined time may be about an hour after the termination of the flow of the silicon-containing precursor, for example. However, other predetermined times indicating a chamber idle period may be chosen. The predetermined time is typically entered by a user into a software routine that includes instructions for controlling the chamber.

The precursor may be introduced into the chamber at a flow rate of between about 0.25 sccm/L and about 150 sccm/L (e.g., between about 50 sccm and about 30000 sccm for a chamber having a volume of about 200 L), for example. The flow rates may be adjusted accordingly for chambers of other sizes. The flow of the precursor may be continued for a period of time, such as between about 100 seconds and about 7200 seconds, without processing a substrate in the chamber, as shown in step 110. The flow of the precursor is then terminated, as shown in step 112. Typically, the supply line that delivers the precursor to the chamber is then purged, such as by flowing a nitrogen gas (N₂) or an inert gas through the line.

If after the flow of the precursor is terminated in step 112, another period of time elapses without another substrate being processed in the chamber, at a predetermined time indicating a chamber idle period, another flow of the precursor may be introduced into the chamber. The flow of the precursor is then terminated, and the supply line that delivers the precursor to the chamber may then be purged as described above. In one aspect, after each period of time of a predetermined length elapses without another substrate being processed in the chamber, a flow of the precursor may be introduced into the chamber. The predetermined time at which the flow of the precursor is introduced into the chamber may be the same for each introduction of the precursor or different.

It has been observed that periodically introducing TEOS into a chamber, as described according to embodiments of the invention, reduced the deviation of the actual TEOS flow into a chamber per unit time from the expected TEOS flow into the chamber per unit time to a value of 2.1% compared to a value of 5.3% that was obtained when TEOS was not flowed periodically into the chamber during chamber idle periods between the processing of substrates.

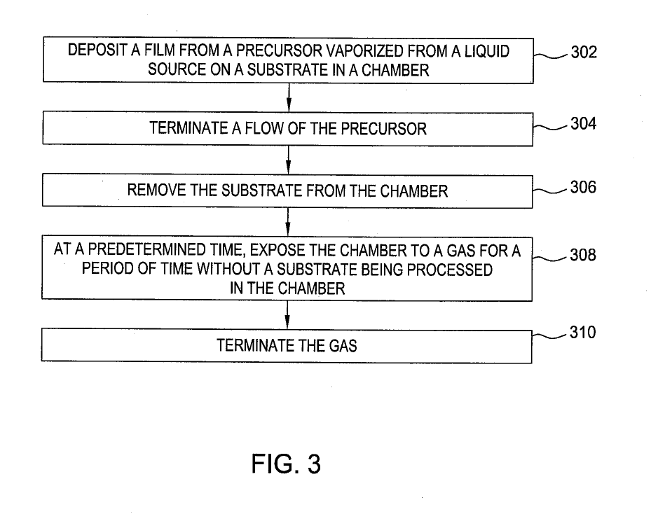

Further embodiments of the invention will be described with respect to FIG. 3. A first flow of a precursor vaporized from a liquid source is introduced into a chamber, and a first film is deposited on a first substrate in the chamber, as summarized in step 302. The first film may be deposited by a vapor deposition process, such as chemical vapor deposition. The precursor and the film may be any of the precursors and films, respectively, described above with respect to FIG. 1.

In an embodiment in which the precursor is TEOS, the TEOS may be introduced into the chamber at a flow rate of between about 0.5 sccm/L and about 11.5 sccm/L, such as between about 1 sccm/L and about 1.5 sccm/L (e.g., between about 100 sccm and about 2300 sccm, such as between about 200 sccm and about 300 sccm, for a chamber having a volume of about 200 L). An inert gas, such as helium or argon, may also be introduced into the chamber as a carrier gas. The chamber pressure during the deposition may be between about 0.5 Torr and about 3 Torr, and the substrate temperature during the deposition may be between about 150° C. and about 440° C. The processing conditions described herein are provided with respect to an AKT-5500 PX chamber.

After the film is deposited on the substrate, the flow of the precursor into the chamber is terminated, as shown in step 304. The substrate is then removed from the chamber, as shown in step 306. Then, if a period of time after the termination of the flow of the precursor elapses without another substrate being processed in the chamber, at a predetermined time, one or more interior surfaces of the chamber are exposed to a gas in the presence or absence of a plasma in the chamber for a period of time, such as between about 100 seconds and about 7200 seconds without a substrate being processed in the chamber, as shown in step 308. The predetermined time may be about an hour after the termination of the flow of the silicon-containing precursor, for example. However, other predetermined times indicating a chamber idle period may be chosen. The predetermined time is typically entered by a user into a software routine that includes instructions for controlling the chamber.

In embodiments in which the one or more interior surfaces of the chamber are exposed to a gas in the presence of plasma, the plasma may be generated by a remote plasma source (RPS) connected to the chamber. In one aspect, the gas may be a cleaning gas, such as NF₃, and the plasma may comprise reactive species generated from the cleaning gas. In another aspect, exposing one or more interior surfaces of the chamber to a gas in the presence of a plasma may comprise a seasoning deposition of a silicon-containing film or another film on one or more interior surfaces of the chamber. Exposing interior surfaces of the chamber to a plasma helps maintain the interior surfaces of the chamber, such as the chamber body, heated, which is beneficial for processes that use liquid precursors.

By exposing the chamber to a plasma during chamber idle periods, a more constant chamber environment may be obtained. It has been observed that when a chamber is in constant deposition mode, i.e., a substrate processing mode without substantial idle periods between substrates, the gas diffuser of the chamber has a low temperature and the chamber body has a high temperature. However, in idle periods, the chamber conditions change from the deposition conditions, as the gas diffuser temperature increases and the chamber body temperature decreases. Exposing the chamber to a plasma or a gas flow to a set pressure or to fill the chamber during chamber idle periods minimizes the change in chamber conditions by decreasing the gas diffuser temperature and increasing the chamber body temperature.

Returning to FIG. 3, the gas and the plasma are then terminated in step 310. If gas and the plasma are terminated, another period of time elapses without another substrate being processed in the chamber, the chamber may be exposed to the gas and plasma again at a predetermined time. The gas and plasma are then terminated. In one aspect, after each period of time elapses without another substrate being processed in the chamber, the chamber may be exposed to the gas and plasma for a period of time.

In embodiments in which the one or more interior surfaces of the chamber are exposed to a gas in the absence of a plasma in step 308, the gas may be hydrogen (H₂) or nitrogen (N₂).

In one embodiment, the hydrogen is introduced into the chamber until a pressure of between about 0.3 Torr and about 20 Torr is achieved in the chamber, such as about 3 Torr. The presence of the hydrogen in the chamber at the desired pressure minimizes the difference between the chamber interior surface temperatures during chamber idle periods and during deposition mode. Minimizing the temperature differences can reduce the period of time that the chamber is under vacuum between depositions, such as from at least 10 hours to about 3-5 hours.

Returning to FIG. 3, the hydrogen is then terminated in step 310. If after the hydrogen is terminated in step 310, another period of time elapses without another substrate being processed in the chamber, the chamber may be exposed to hydrogen again at a predetermined time. The hydrogen is then terminated. In one aspect, after each period of time elapses without another substrate being processed in the chamber, the chamber may be exposed to hydrogen for a period of time.

In another embodiment, nitrogen is flowed into the chamber for a period of time. The nitrogen may be flowed into the chamber at a rate between about 0.5 sccm/L and about 100 sccm/L (e.g., between about 100 sccm and about 20000 sccm for a chamber having a volume of about 200 L). The chamber pressure may be between about 300 mTorr and about 20000 mTorr, and the spacing between the gas diffuser and the substrate support in the chamber may be between about 500 mils and about 2000 mils. For example, the nitrogen may be flowed in at a rate of 15 sccm/L (e.g., 3000 sccm for a chamber having a volume of about 200 L) with a chamber pressure of 1500 mTorr and a spacing of 1500 mils. Flowing the nitrogen gas into the chamber contributes to achieving and maintaining a selected temperature for the gas diffuser, such as between about 320° C. and about 330° C.

Returning to FIG. 3, the nitrogen is then terminated in step 310. If after the nitrogen is terminated in step 310, another period of time elapses without another substrate being processed in the chamber, the chamber may be exposed to nitrogen again at a predetermined time. The nitrogen is then terminated. In one aspect, after each period of time elapses without another substrate being processed in the chamber, the chamber may be exposed to nitrogen for a period of time.

While the embodiments of FIGS. 1 and 3 are described separately above, in a further embodiment, a method of processing substrates includes both exposing one or more interior surfaces of a chamber to a gas in the presence or absence of a plasma at a predetermined time for a first period of time without a substrate being processed in the chamber, as described above with respect to FIG. 3, and introducing a second flow of a precursor into a chamber at a predetermined time and continuing the second flow of the precursor for a second period of time without a substrate being processed in the chamber, as described above with respect to FIG. 1.

Computer storage media are provided according to further embodiments of the invention. The computer storage media contain software routines that cause a general purpose computer to control a chamber using a deposition method. The software routine may be included in a computer storage medium 272 in a controller 270 connected to a chamber, as shown in FIG. 2. The software routines comprise instructions for the methods described above with respect to FIGS. 1 and 3. For example, in one embodiment, a software routine comprises instructions for introducing a first flow of a precursor vaporized from a liquid source into a chamber and depositing a first film on a first substrate in a chamber, terminating the first flow of the precursor into the chamber, removing the first substrate from the chamber, and then introducing a second flow of the precursor into the chamber at a predetermined time indicating a chamber idle period after terminating the first flow of the silicon-containing precursor into the chamber, wherein no substrates are processed in the chamber between the removing the first substrate and the introducing the second flow of the precursor, and continuing the second flow of the precursor for a first period of time without a substrate being processed in the chamber. In another embodiment, a software routine comprises instructions for introducing a first flow of a precursor into a chamber and depositing a first film on a first substrate in the chamber, terminating the first flow of the precursor into the chamber, removing the first substrate from the chamber, and at a predetermined time indicating a chamber idle period after terminating the first flow of the precursor into the chamber and after the first substrate is removed from the chamber, exposing one or more interior surfaces of the chamber to a gas in the presence or absence of a plasma for a first period of time without a substrate present being processed in the chamber, wherein no substrates are processed in the chamber between the removing the exposing one or more interior surfaces of the chamber to the gas.

While the foregoing is directed to embodiments of the present invention, other and further embodiments of the invention may be devised without departing from the basic scope thereof, and the scope thereof is determined by the claims that follow.

What is claimed is:

1. A method of processing substrates, comprising:
introducing a first flow of a precursor vaporized from a liquid source into a chamber and depositing a first film on a first substrate in the chamber;
terminating the first flow of the precursor into the chamber;
removing the first substrate from the chamber; and then
introducing a second flow of the precursor into the chamber at a predetermined time indicating a chamber idle period after terminating the first flow of the precursor into the chamber, wherein no substrates are processed in the chamber between the removing the first substrate and the introducing the second flow of the precursor, and continuing the second flow of the precursor for a first period of time without a substrate being processed in the chamber.

2. The method of claim 1, wherein the precursor is TEOS.

3. The method of claim 1, wherein the first period of time is between about 100 seconds and about 7200 seconds.

4. The method of claim 1, further comprising introducing a second substrate into the chamber after the first period of time.

5. The method of claim 4, further comprising:
terminating the second flow of the precursor; and
at a predetermined time indicating a chamber idle period after terminating the second flow of the precursor, introducing a third flow of the precursor into the chamber and continuing the third flow of the precursor for a second period of time without a substrate being processed in the chamber, wherein the third flow is introduced before the second substrate is introduced into the chamber, and wherein no substrates are processed in the chamber between the terminating the second flow of the precursor and the introducing the third flow of the precursor.

6. The method of claim 4, further comprising depositing a second film on the second substrate in the chamber.

7. The method of claim 1, wherein the first layer is a silicon oxide layer.

8. The method of claim 1, wherein the first flow of the precursor and the second flow of the precursor are introduced into the chamber from a supply line, and the supply line is purged after the first period of time.

9. The method of claim 8, further comprising:
terminating the second flow of the precursor before purging the supply line; and
at a predetermined time indicating a chamber idle period after terminating the second flow of the precursor, introducing a third flow of the precursor into the chamber and continuing the third flow of the precursor for a second period of time without a substrate being processed in the chamber, wherein the third flow is introduced before a second substrate is introduced into the chamber.

10. The method of claim 8, wherein purging the supply line comprises flowing nitrogen gas or an inert gas through the supply line.

11. A method of processing substrates, comprising:
introducing a first flow of a precursor vaporized from a liquid source into a chamber and depositing a first film on a first substrate in the chamber;
terminating the first flow of the precursor into the chamber;
removing the first substrate from the chamber; and
at a predetermined time indicating a chamber idle period after terminating the first flow of the precursor into the chamber and after the first substrate is removed from the chamber, exposing one or more interior surfaces of the chamber to a gas in the presence or absence of a plasma for a first period of time without a substrate being processed in the chamber, wherein no substrates are processed in the chamber between the removing the first substrate and the exposing one or more interior surfaces of the chamber to the gas.

12. The method of claim 11, wherein the one or more interior surfaces of the chamber are exposed to the gas in the absence of a plasma, and the gas is selected from the group consisting of hydrogen and nitrogen.

13. The method of claim 11, further comprising introducing a second substrate into the chamber after the first period of time.

14. The method of claim 11, wherein the one or more interior surfaces of the chamber are exposed to the gas in the presence of a plasma.

15. The method of claim 14, wherein the plasma is generated by a remote plasma source.

16. The method of claim 14, wherein the plasma comprises a cleaning gas.

17. The method of claim 14, wherein exposing one or more interior surfaces of the chamber to a plasma comprises depositing a seasoning film on one or more interior surfaces of the chamber.

18. The method of claim 11, further comprising:
introducing a second flow of the precursor into the chamber at a predetermined time after terminating the first flow of the precursor into the chamber and continuing the second flow of the precursor for a second period of time without a substrate being processed in the chamber.

19. The method of claim 11, wherein the precursor is TEOS.

20. A computer storage medium containing a software routine that, when executed, causes a general purpose computer to control a chamber using a deposition method, wherein the software routine comprises instructions for:
introducing a first flow of a precursor vaporized from a liquid source into a chamber and depositing a first film on a first substrate in the chamber;
terminating the first flow of the precursor into the chamber;
removing the first substrate from the chamber; and then
introducing a second flow of the precursor into the chamber at a predetermined time indicating a chamber idle period after terminating the first flow of the precursor into the chamber, wherein no substrates are processed in the chamber between the removing the first substrate and the introducing the second flow of the precursor, and continuing the second flow of the precursor for a first period of time without a substrate being processed in the chamber.

21. The computer storage medium of claim 20, wherein the software routine further comprises instructions for introducing a second substrate into the chamber after the first period of time.

22. The computer storage medium of claim 20, wherein the software routine further comprises instructions for:
terminating the second flow of the precursor; and
at a predetermined time indicating a chamber idle period after terminating the second flow of the precursor, introducing a third flow of the precursor into the chamber and continuing the third flow of the precursor for a second period of time without a substrate being processed in the chamber, wherein the third flow is introduced before the second substrate is introduced into the chamber, and wherein no substrates are processed in the chamber between the terminating the second flow of the precursor and the introducing the third flow of the precursor.

23. A computer storage medium containing a software routine that, when executed, causes a general purpose computer to control a chamber using a deposition method, wherein the software routine comprises instructions for:
introducing a first flow of a precursor into a chamber and depositing a first film on a first substrate in the chamber;
terminating the first flow of the precursor into the chamber;
removing the first substrate from the chamber; and
at a predetermined time indicating a chamber idle period after terminating the first flow of the precursor into the chamber and after the first substrate is removed from the chamber, exposing one or more interior surfaces of the chamber to a gas in the presence or absence of a plasma for a first period of time without a substrate being processed in the chamber, wherein no substrates are processed in the chamber between the removing the first substrate and the exposing one or more interior surfaces of the chamber to a gas.

24. The computer storage medium of claim 23, wherein the software routine further comprises instructions for introducing a second substrate into the chamber after the first period of time.

25. The computer storage medium of claim 23, wherein the software routine further comprises instructions for:
introducing a second flow of the precursor into the chamber at a predetermined time indicating a chamber idle period after terminating the first flow of the precursor into the chamber and continuing the second flow of the precursor for a second period of time without a substrate being processed in the chamber.
